(19) United States
(12) Patent Application Publication
(10) Pub. No.: US 2026/0239577 A1
(43) Pub. Date: Aug. 13, 2026

(54) Cooling Air Augmentation

(71) Applicant: Microsoft Technology Licensing, LLC, Redmond, WA (US)

(72) Inventor: Freddie BELL, JR., Ashburn, VA (US)

(73) Assignee: Microsoft Technology Licensing, LLC, Redmond, WA (US)

(21) Appl. No.: 19/051,487

(22) Filed: Feb. 12, 2025

(51) Int. Cl. H05K 7/20

(52) U.S. Cl. CPC H05K 7/20745; H05K 7/20145; H05K 7/20836

(57) ABSTRACT

The description relates to thermal management and ensuring adequate cooling of individual computing devices where multiple computing devices operate in proximity to one another. One example can obtain sensed conditions within a rack containing multiple computing devices. The rack receives cooling air from a centralized cooling system. The example can control delivery of make-up cooling air to individual computing devices within the rack to augment the cooling air from the centralized cooling system to remove thermal loads from the individual computing devices.

### BACKGROUND

Many computing scenarios involve large numbers of computing devices positioned in close physical proximity. For instance, data centers often involve hundreds or thousands of computing devices, such as servers in proximity to one another. These computing devices generate large amounts of heat that must be removed for the computing devices to operate safely.

### SUMMARY

This patent relates to thermal management and ensuring adequate cooling of individual computing devices where multiple computing devices operate in proximity to one another. One example includes a rack configured to receive cooling air through a front side and to evacuate warm air through an opposing back side. A make-up cooling assembly is positioned proximate to the rack and includes an auxiliary air conditioning unit configured to generate additional cooling air and a rack distribution sub-assembly configured to selectively deliver the additional cool air to locations within the rack to augment the received cooling air.

Another example can obtain sensed conditions within a rack containing multiple computing devices. The rack receives cooling air from a centralized cooling system. This example can control delivery of make-up cooling air to individual computing devices within the rack to augment the cooling air from the centralized cooling system to remove thermal loads from the individual computing devices.

This Summary is intended to briefly introduce some of the present concepts and is not intended to be inclusive or limiting.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the figure and associated discussion where the reference number is first introduced. Where space permits, elements and their associated reference numbers are both shown on the drawing page for the reader's convenience. Otherwise, only the reference numbers are shown.

FIGS. 1A, 1B, 2C, 3A-3C, 5A, 5B, 6, and 8 show perspective views of example systems and devices in accordance with some implementations of the present concepts.

FIGS. 2A, 2B, 3D, 3E, 4A, 4B, and 7 show elevational views of example devices and systems in accordance with some implementations of the present concepts.

FIGS. 9 and 10 show example flowcharts for accomplishing methods in accordance with some implementations of the present concepts.

### DETAILED DESCRIPTION

The present concepts relate to cooling computing devices that are in physical proximity to one another. Many computing scenarios involve large numbers of computing devices positioned in close physical proximity. For instance, data centers often involve hundreds or thousands of computing devices, such as servers in proximity to one another. These computing devices generate large amounts of heat that must be removed for the computing devices to operate safely. This heat dissipation (e.g., thermal management) issue becomes more pronounced as computing devices, such as servers offer higher computing performance, such as faster clock times, more processing units, etc.

Datacenters include physical structures (e.g., buildings) and infrastructure to protect the computing devices and to facilitate their function. The infrastructure includes power supplies, network connections and centralized cooling systems. The centralized cooling systems are sized to provide a specified amount of cooling to the inside of the building to cool the computing devices. Generally, computing devices are arranged on multiple shelves of a rack and multiple racks are arranged in rows. The rows of racks are positioned along cold air aisles. The frontside of two opposing racks face a cold air aisle. The backside of the racks face a hot air plenum or heat return plenum. The backsides of racks of adjacent cold air aisles face the hot air plenum so that the hot air plenum is sandwiched between two sets of parallel racks.

The central cooling system supplies pressurized cool (e.g., cooling) air to the cold air aisles. The cool air enters the racks and removes heat from the computing devices positioned in the racks and exits out the hot air plenum (e.g., is expelled to the external environment). The centralized cooling system can be sized to provide sufficient cooling capacity for an intended total number of computing devices the datacenter is configured to hold (e.g., total rack spaces/positions). For instance, sufficient cooling capacity can be based upon the number of rack positions that can receive computing devices for all shelves on all racks. The overall thermal management requirements can be determined from the number of rack positions and the thermal load of the individual computing devices that can occupy the rack positions (e.g., thermal load per computing device multiplied by the number of computing devices).

However, in practice, localized over-demand for cooling can occur even though the overall cooling capacity provided by the centralized cooling system is adequate. For instance, this localized over-demand could occur in racks facing one another across a cold air aisle. If highly performing computing devices are positioned in both of these opposing racks, sufficient cooling air flow may not be available to adequately cool all of these computing devices. This can be termed ‘localized over-demand.’ This localized over-demand is exacerbated when computing devices are upgraded to higher performance models that in turn produce more heat than the models originally utilized in determining the overall thermal load.

The localized over-demand creates localized cooling starvation where there is not enough localized cooling capacity for the computing devices at an individual location. Stated another way, despite the centralized cooling system potentially providing sufficient total cooling capacity for the rack spaces in the datacenter, in individual local areas, insufficient central cooling airflow is available to remove the thermal load of the local computing devices. Traditionally, this technical problem is addressed by not positioning computing devices in all of the available rack positions. For instance, if high performance computers are positioned in one rack, then the opposing rack across the cold air aisle is left empty or sparsely populated with computing devices. Alternatively or additionally, if computing devices are positioned in more (or all) of the available rack positions, individual computing devices cannot be operated at their designed specifications. For instance, the computing devices may have to be throttled to reduce their thermal load to match the available cooling from the centralized cooling system.

This technical problem has traditionally caused inefficient use (e.g., underutilization) of data center space and/or diminished computing performance to avoid overheating of these local computing devices. The present concepts provide a technical solution to this technical problem with localized cooling air augmentation to local computing devices that would otherwise be subject to localized cooling starvation.

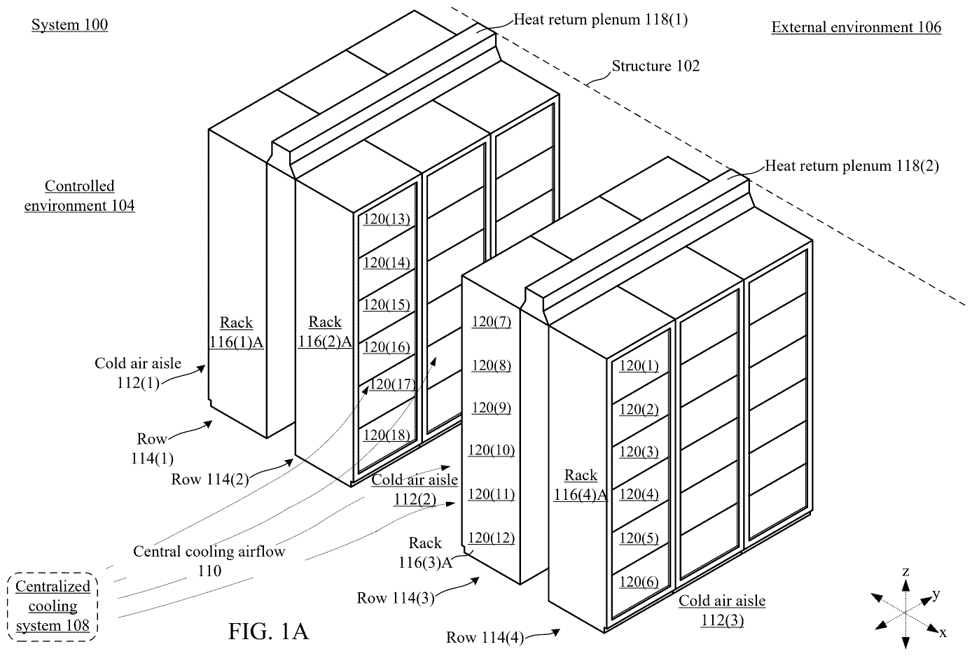

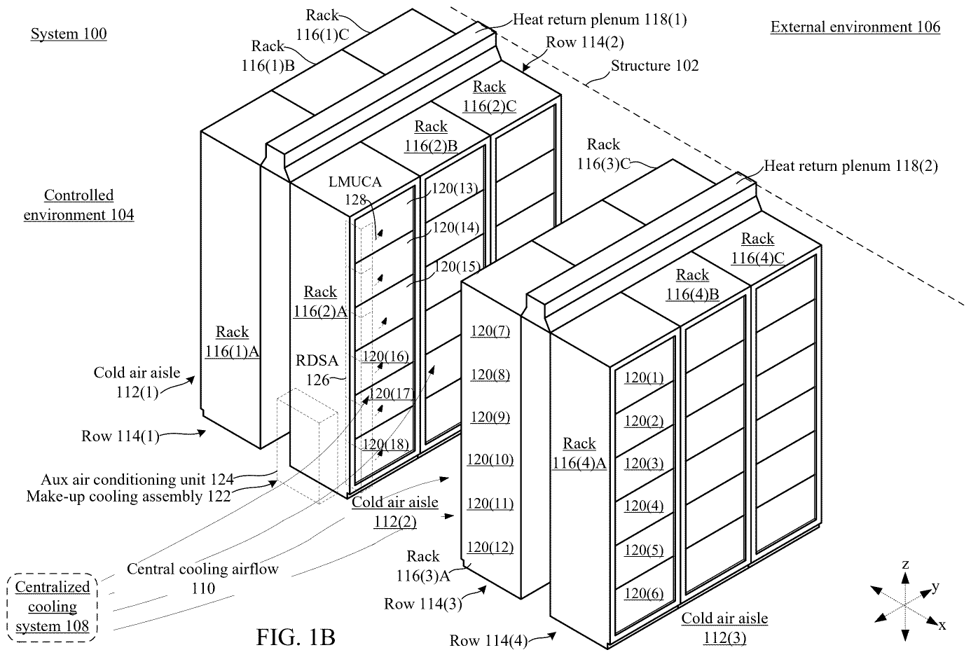

The technical solution is accomplished with focused and controlled auxiliary (e.g., make-up) cool air flow that delivers deliberate computing device cool airflow to make up for localized cool airflow deficiencies from the cold air aisle as supplied by the centralized cooling system. This technical solution reduces/eliminates reliance on the existing undesirable technique of staggering computing device placement or leaving entire racks vacant when computing devices in opposing racks have large cooling requirements. Thus, the present solutions allow computing devices to be positioned according to data center design and allow the computing devices to be operated according to design specifications without overheating. Some of these aspects are explained in more detail below relative to FIGS. 1A and 1B.

FIGS. 1A and 1B collectively show an example system 100 implementing some of the localized cooling air augmentation concepts. The illustrated portion of the system 100 includes a structure 102, such as a physical building that provides a border between a controlled environment 104 and an external environment 106. The system includes a centralized cooling system 108 that provides a specified amount of central cooling air or airflow 110 to the inside of the structure 102. The structure 102 includes cold air aisles 112. Rows 114 of racks 116 are positioned along the cold air aisles 112. Two opposing racks 116 face adjacent cold air aisles and are separated by hot (return) air plenums 118. Computing devices 120 are arranged on multiple shelves of individual racks 116. To avoid clutter on the drawing page only some of the computing devices 120 are shown, specifically, computing devices 120(1)-120(6) are shown in rack 116(4)A, computing devices 120(7)-120(12) are shown in rack 116(3)A, and computing devices 120(13)-120(18) are shown in rack 116(2)A. In practice, more computing devices could be positioned in each rack. Further, though not shown, the remaining racks would also include computing devices 120.

The central cooling system 108 supplies pressurized central cooling air 110 to the cold air aisles 112. The central cooling air 110 enters the racks 116 and removes heat from the computing devices 120 positioned in the racks and exits out the hot air plenum or hot air return plenum 118. However, as mentioned above, cool air flow may be insufficient to remove the heat load from specific local areas of the controlled environment, such as within individual racks 116 or portions of racks 116. As shown in FIG. 1B, a make-up air cooling assembly 122 can be deployed in the system 100 to address these localized cooling deficiencies.

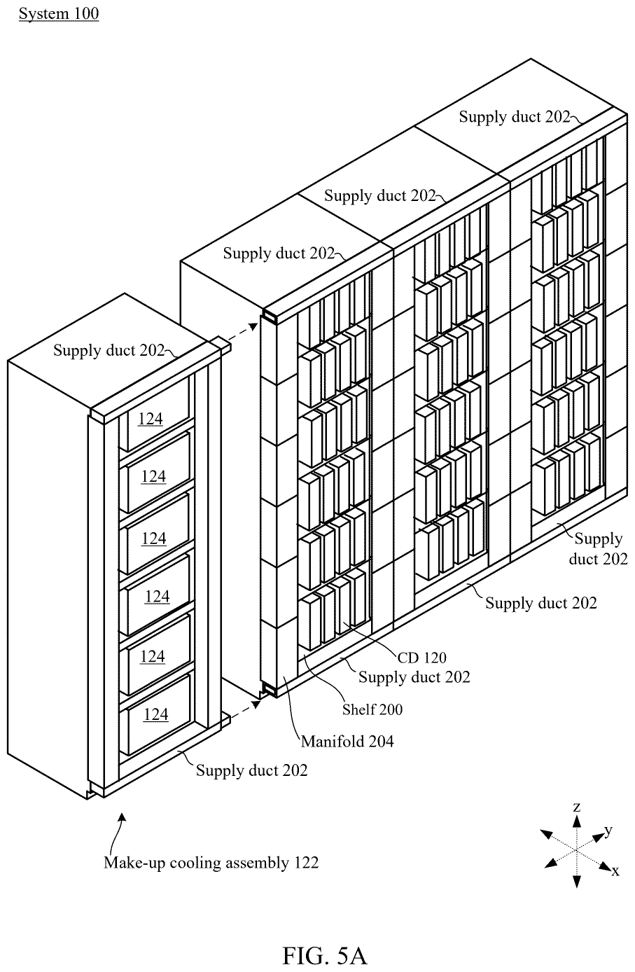

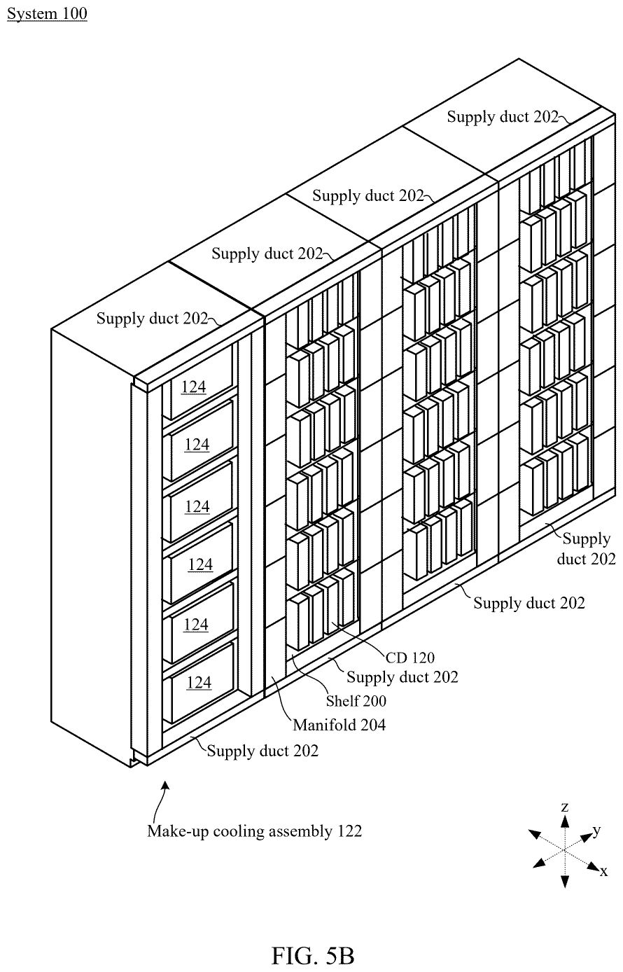

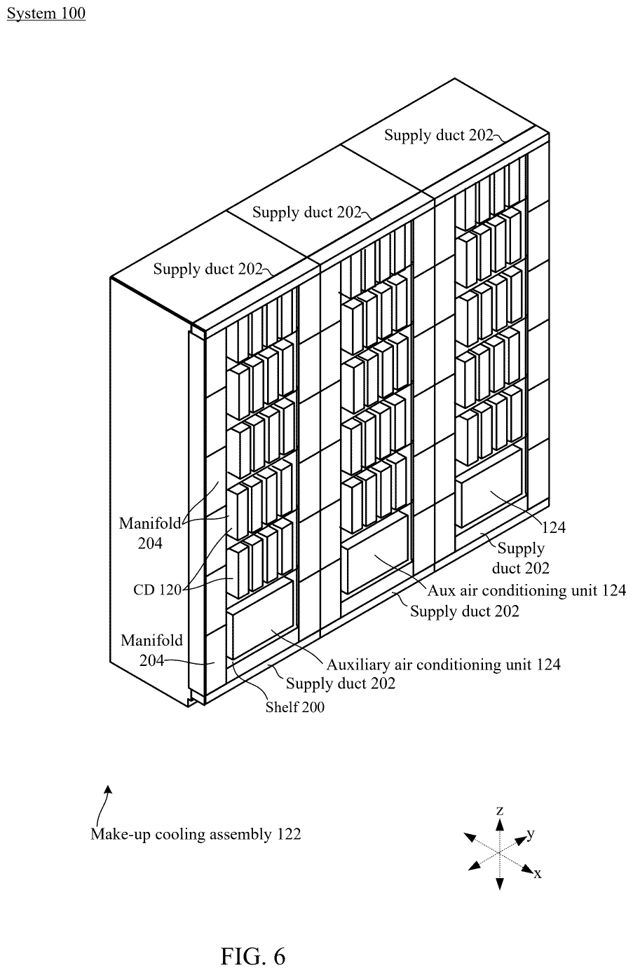

In this illustrated implementation, make-up air cooling assembly 122 includes an auxiliary air conditioning unit 124 and a rack distribution sub-assembly 126. The auxiliary air conditioning unit 124 can be positioned proximate to individual racks 116. In this implementation, the auxiliary air conditioning unit 124 is positioned adjacent to rack 116(2)A. The auxiliary air conditioning unit 124 can augment cool air supply to computing devices 120 in one or more of the racks 116(2) in row 114(2). Alternative implementations are described below relative to FIGS. 5A and 5B where the auxiliary air conditioning unit 124 is positioned in one of the racks 116 to supply multiple racks with localized make-up cooling air. Still another implementation is described below relative to FIG. 6 where auxiliary air conditioning units 124 are positioned in racks 116 to supply that individual rack with ‘localized make-up cooling air’ (LMUCA) 128.

Auxiliary air conditioning unit 124 receives air and may further cool the received air to produce auxiliary or additional cool air. Heat from the auxiliary air conditioning unit 124 is evacuated to the hot air return plenum 118. The auxiliary cool air from the auxiliary air conditioning unit 124 is delivered to the rack distribution sub-assembly 126. The rack distribution sub-assembly 126 delivers the cooler air as localized make-up cool air 128 to individual computing devices 120, which would otherwise be subject to cooling starvation. Note that several arrows representing localized make-up cool air are shown in rack 116(2)A, but only one of these arrows is labelled to avoid clutter on the drawing page. This technical solution allows these computing devices 120(14)-120(18) or some subset thereof, that would otherwise experience localized cooling starvation, and which would otherwise have to be throttled, to be operated as desired up to full design specifications.

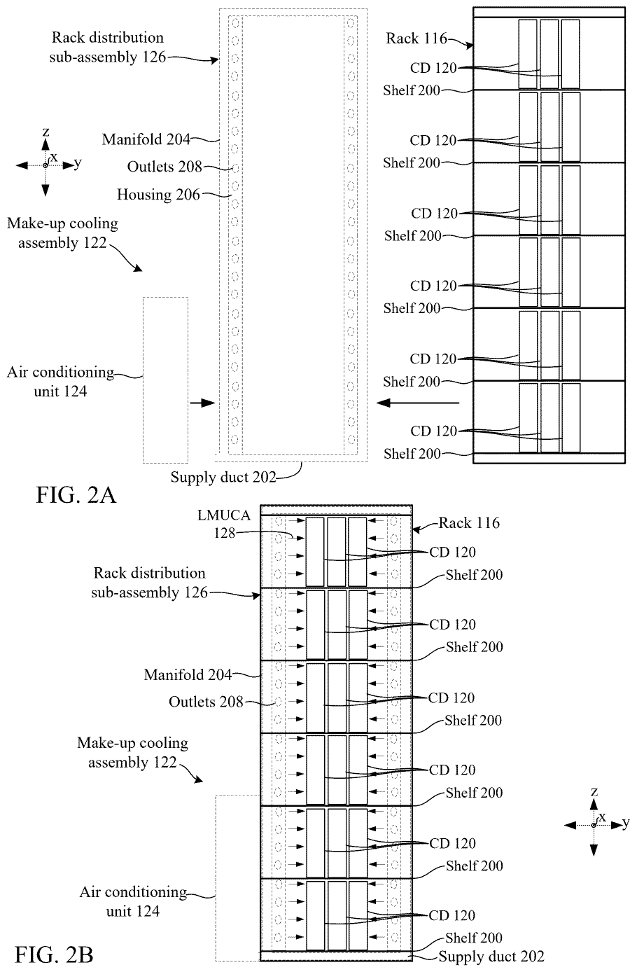

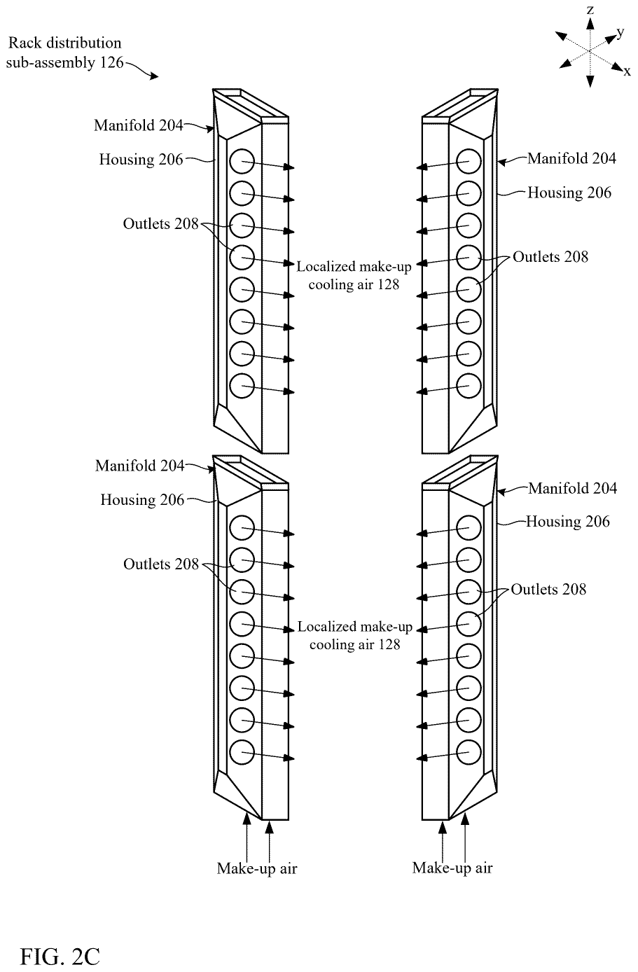

FIGS. 2A-2C collectively show the make-up cooling assembly 122 introduced in FIG. 1B. FIG. 2A shows auxiliary air conditioning unit 124, rack distribution sub-assembly 126, and rack 116 in isolation (e.g., in an unassembled state). Computing devices 120 are positioned on shelves 200 in the rack 116. FIG. 2B shows the rack distribution sub-assembly 126 assembled on the rack 116 and fluidly coupled to the auxiliary air conditioning unit 124.

In this case, the auxiliary air conditioning unit 124 is positioned adjacent to the rack 116 (e.g., within the row), similar to the implementation shown in FIG. 1B. The rack distribution sub-assembly 126 includes supply ducts 202 and manifolds (e.g., airflow rails) 204. The manifolds 204 include a housing 206 that defines outlets 208. The supply ducts 202 extend through the rack 116 or along the front of the rack (e.g., the cold air aisle side). The supply ducts 202 receive cool air from the auxiliary air conditioning unit 124 and distribute the cool air to the manifolds 204. The manifolds 204 define outlets 208 (e.g., holes or other features) that direct the cool air towards specific locations (e.g., specific computing devices) in the rack that would otherwise experience localized cooling starvation.

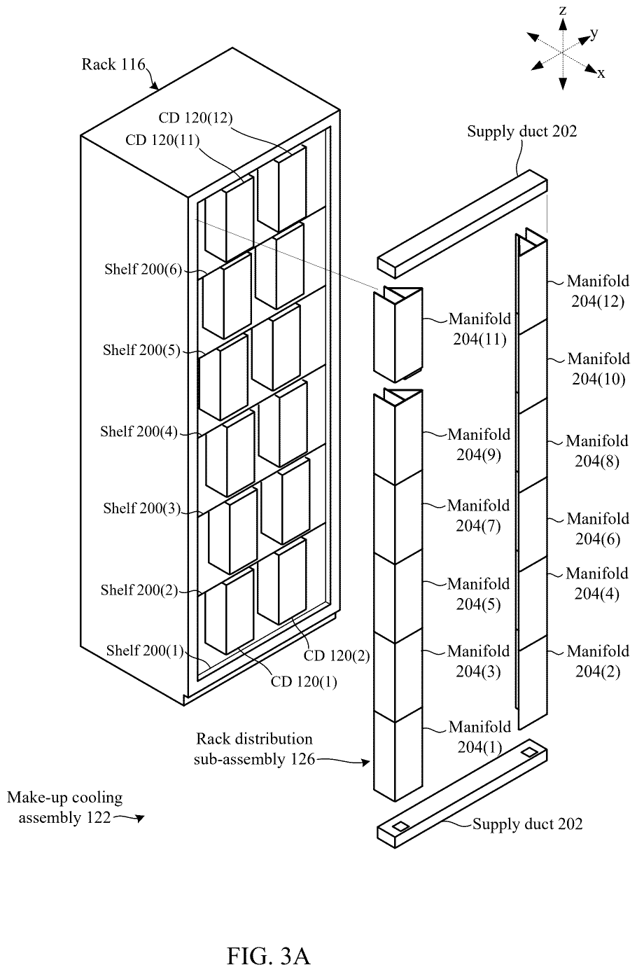

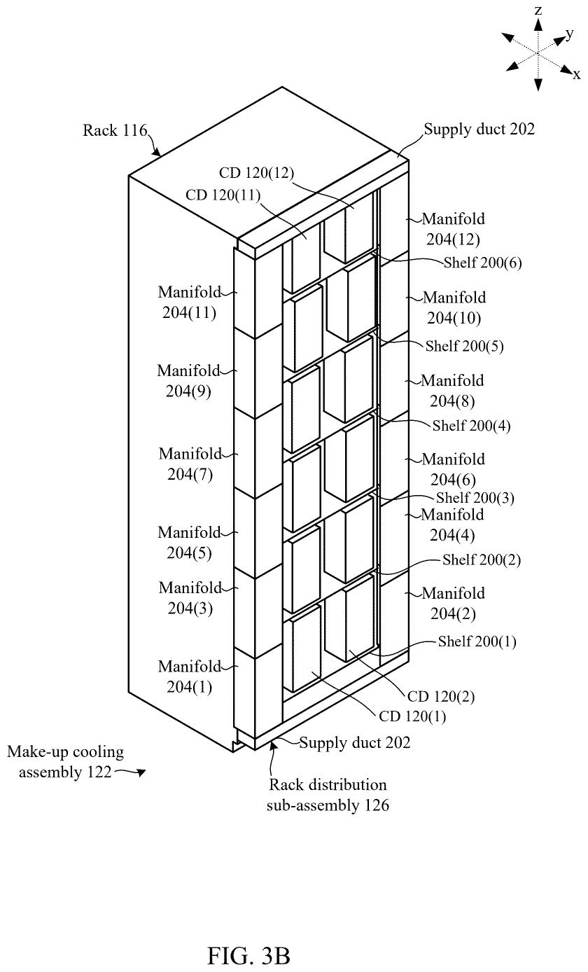

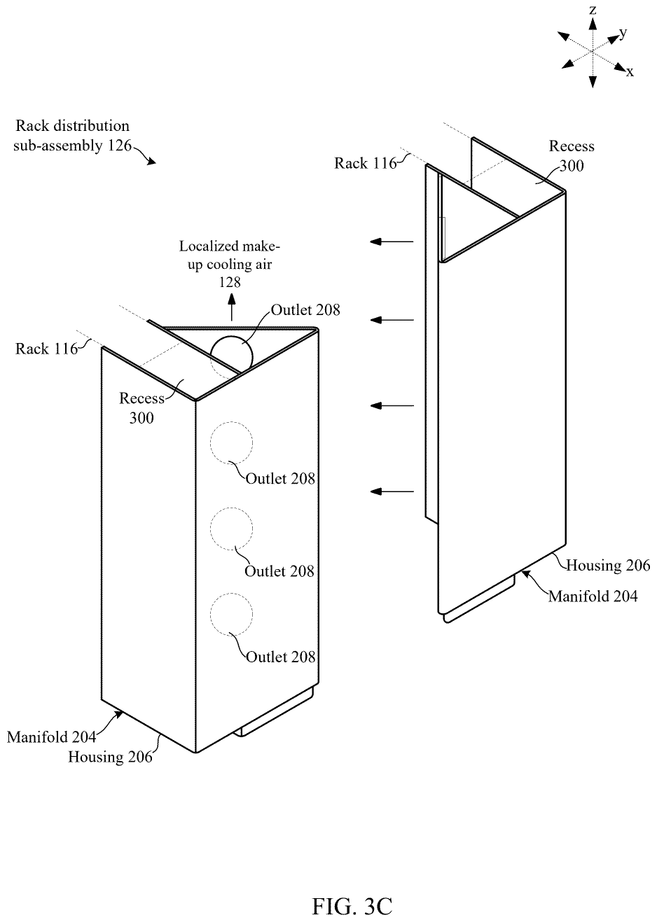

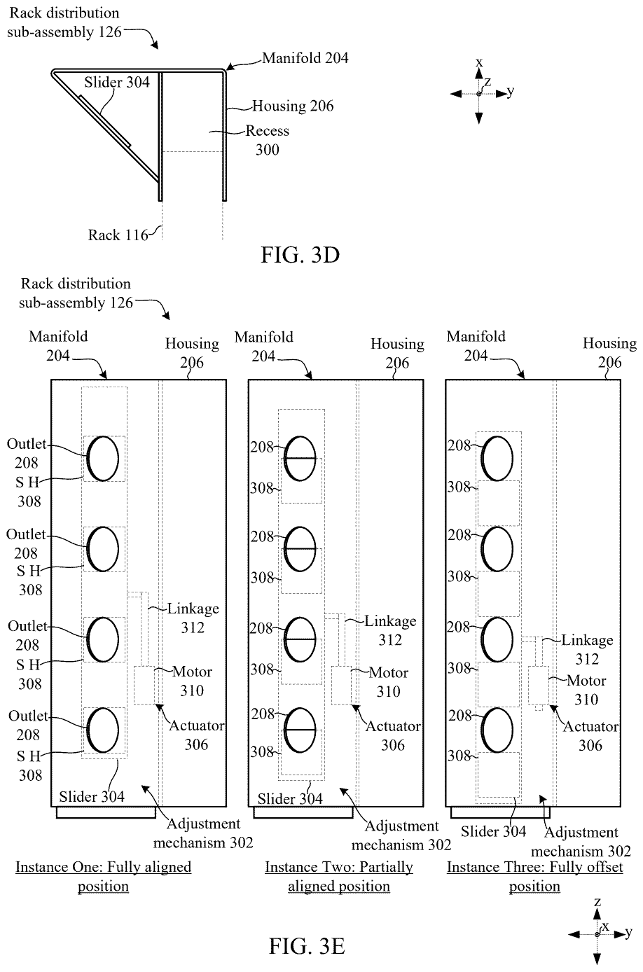

In some manifold configurations, the outlets 208 of an individual manifold 204 provide a fixed or non-adjustable airflow outlet. Other manifold configurations offer adjustable airflow. One such manifold configuration is shown and described relative to FIG. 3E.

FIGS. 3A-3E collectively show another make-up cooling assembly 122. Note that the auxiliary air conditioning unit 124 is not shown on these views to avoid clutter on the drawing page. While not shown, the auxiliary air conditioning unit 124 can be coupled to the rack distribution sub-assembly 126 as shown in FIGS. 1B and 2B. FIG. 3A shows an unassembled rack distribution sub-assembly 126 in front of rack 116. The rack 116 includes multiple shelves 200 with multiple computing devices 120 positioned on individual shelves. In this example, twelve computing devices are shown on six shelves 200. However, only computing devices (CD) 120(1), 120(2), 120(11), and 120(12) are labelled to reduce clutter on the drawing page. FIG. 3B shows the rack distribution sub-assembly 126 assembled on rack 116. FIG. 3C shows a close-up view of two of the rack distribution sub-assembly's manifolds 204. This FIG. also shows an example where the housing 206 forms a recess 300 that can receive the rack 116. The recess 300 allows the manifold 204 to be readily secured to, and removed from, the rack 116.

FIG. 3E shows an air flow adjustability aspect of this implementation that allows auxiliary cool air flow to be adjusted for particular locations within a rack. In this case, the air flow adjustability aspect is accomplished with an adjustment mechanism 302 that operates relative to an individual manifold 204. In this implementation, the adjustment mechanism 302 is behind the housing (e.g., within the manifold) and as such is shown in ghost.

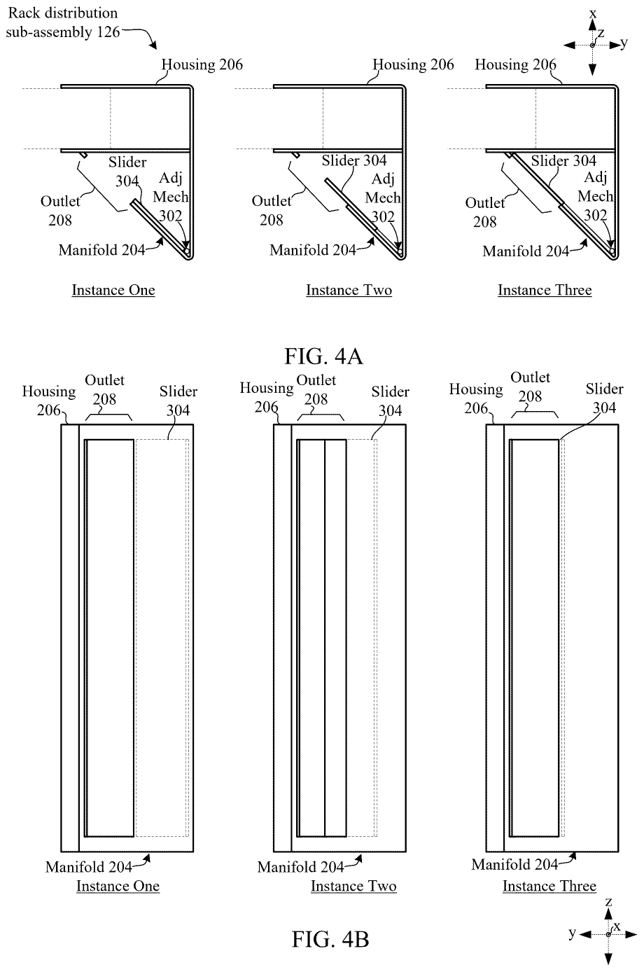

In this example, the cool air flow adjustment mechanism 302 includes a slider 304 and an actuator 306. The slider 304 defines secondary outlets 308, such as holes. The actuator 306 includes an electric motor 310 and a linkage 312 that couples the motor 310 to the slider 304 to allow the motor to drive the position of the slider. As mentioned, the slider 304 defines secondary outlets 308. Note that in the illustrated configuration, the outlets 208 are rounded (e.g., elliptical) and the secondary outlets 308 are rectangular. Other configurations are contemplated. For instance, both the outlets 208 and the secondary outlets 308 could be the same shape, such as a regular shape or an irregular shape. Further this implementation includes multiple outlets 208 and multiple secondary outlets 308 per manifold. An alternative configuration is described relative to FIGS. 4A and 4B.

The degree to which the secondary outlets 308 are aligned with the outlets 208 determines the relative cool air flow from the manifold 204. Stated another way, the alignment of the outlets 208 and the secondary outlets 308 controls the amount of localized make-up cooling air 128 delivered from the individual manifold 204. For purposes of illustration, FIG. 3E shows three example alignments: a fully aligned position of Instance One, a partially aligned position of Instance Two, and a fully offset position of Instance Three. In the fully aligned position, the secondary outlets 308 do not limit the amount of air (e.g., localized make-up cooling air 128) that would otherwise flow through the outlets 208. Stated another way, the secondary outlets 308 do not limit the ‘open’ area of the outlets 208. In the partially aligned position, the secondary outlets 308 decrease the effective ‘open’ area of the outlets 208 and thereby restrict airflow (e.g., localized make-up cooling air 128) compared to the fully aligned position. In the fully offset position, the secondary outlets 308 effectively block the outlets 208 and thereby restrict airflow from the outlets 208 (e.g., no localized make-up cooling air 128 is emitted from this individual manifold 204). Note that while only one partially aligned or intermediate position is illustrated, an essentially infinite number of positions are available to adjust the airflow between the fully aligned position (e.g., fully open) and the fully offset position (e.g., fully closed).

In this configuration, cool air flow adjustment mechanism 302 customizes localized make-up cooling air 128 from the manifold 204 by adjusting the effective size of the outlets 208. In this implementation, the cool air flow adjustment mechanism 302 includes the outlets 208 as well as slider 304. The slider 304 extends along the housing 206. The slider 304 defines secondary outlets 308. The slider 304 is moveable by actuator 306. In this case, the actuator 306 is manifest as an electric motor 310 that is mechanically coupled to the slider 304 by linkage 312. In this example, the linkage 312 entails rack and pinion gears. Other actuator and linkage configurations are contemplated.

The actuator 306 can be controlled (e.g., powered) to move the slider 304 relative to the housing 206. Instance one shows the slider 304 positioned by the actuator 306 so that the secondary outlets 308 of the slider 304 are fully aligned with the outlets 208 in the housing 206. At a given auxiliary cool air flow pressure within the manifold 204, this alignment allows a relatively high (or highest) volume of localized make-up cooling air 128 out of the manifold 204 and onto the local computing devices. Instance two shows the slider 304 positioned by the actuator 306 so that the secondary outlets 308 of the slider 304 are partially aligned with the outlets 208 in the housing 206 (e.g., an intermediate position). This alignment allows an intermediate volume of localized make-up cooling air 128 from the manifold 204 and onto the local computing devices. Instance three shows the slider 304 positioned by the actuator 306 so that the secondary outlets 308 of the slider 304 are not aligned with the outlets 208 in the housing 206. This alignment (or misalignment) allows a relatively low (or no) volume of localized make-up cooling air 128 out of the manifold 204 and onto the local computing devices. While only one intermediate position is shown, a large number of intermediate positions are possible to precisely adjust the airflow from the outlets 208 to accommodate the heat load of the individual computing devices in this location (e.g., on this shelf (or portion of this shelf) of the rack).

The illustrated implementation allows localized make-up airflow control of individual manifolds. In this case, the individual control is achieved by a one-to-one relationship between adjustment mechanisms 302 and manifolds 204. Thus, air flow from individual manifolds can be controlled independently of the airflow from other manifolds. This independent air flow control allows make up cool air to be delivered to individual locations within an individual rack, such as individual shelves, portions of shelves, or even individual computing devices, thus the term ‘localized make-up cooling air’ 128. This aspect can be explained in reference to FIG. 3B, in light of the explanation above relative to FIG. 3E.

In relation to FIG. 3B in combination with FIG. 3E, consider a scenario where computing device 120(1) is experiencing extreme localized cooling air starvation, computing device 120(2) is experiencing a lesser degree of localized cooling air starvation, and the remaining computing devices are receiving sufficient cooling air from the centralized cooling system 108 of FIG. 1A. In this scenario, adjustment mechanism 302(1) associated with manifold 204(1) can be controlled to provide relatively high localized make-up cooling air flow from this manifold 204(1) by moving the slider 304 to the fully aligned position. Similarly, adjustment mechanism 302(2) associated with manifold 204(2) can be controlled to provide intermediate localized make-up cooling air flow from this manifold 204(2) by moving the slider 304 (vertically) to a partially aligned position. Finally, the remaining adjustment mechanisms 302 associated with the remaining manifolds 204(3)-204(12) can be controlled to limit or block localized make-up airflow to shelves 200(2)-200(6) by moving the sliders 304 to the fully offset position. This configuration provides sufficient localized make-up cooling airflow to computing devices 120(1) and 120(2) so they do not have to be throttled or shut down.

FIGS. 4A and 4B collectively show another example manifold 204 that includes housing 206 that defines a single outlet 208. Note that a single larger outlet 208 is employed in this implementation. However, multiple smaller outlets, such as holes could be employed similar to the implementation illustrated in FIGS. 3A-3E. The flow of localized make-up cool air flow from the outlet 208 is controlled by the adjustment mechanism 302 moving the slider 304 (horizontally) relative to the housing 206 (e.g., relative to the outlet 208). In this case, the adjustment mechanism's slider 304 adjusts air flow through the outlet 208 by moving to obscure none (Instance one), some portion (Instance two), or all (Instance three) of the outlet 208. Thus, manifold 204 provides customized local make-up cool air augmentation to remove the heat load of local (e.g., individual) computing devices. The adjustment mechanism 302 can dynamically change the air flow through the outlet 208 to handle a changing thermal load of the computing devices that are proximate to the manifold 204.

FIGS. 5A and 5B collectively show another example system 100. In this case, the make-up cooling assembly 122 is positioned in one of the racks 116 of a row 114. In this example, rack 116(1) includes auxiliary air conditioning units 124. Racks 116(2)-116(4) include multiple shelves 200, with each shelf 200 holding multiple computing devices 120. (To avoid clutter on the drawing page, only one manifold 204, one shelf 200, and one computing device 120 are specifically labeled.) The auxiliary air conditioning units 124 are connected to supply ducts 202 which are in turn connected to the manifolds 204. The manifolds are controllable as described above relative to FIGS. 3A-3E and 4A-4B to provide localized make-up cooling air to locations within the racks 116(2)-116(4) in row 114. This system configuration maintains the existing footprint within the structure and thus does not impinge on walkway dimensions between rows or cold air aisle dimensions. Thus, utilizing all or part of one rack for auxiliary air conditioning units 124 provides a technical solution that allows the other racks 116 to be filled with computing devices 120 and for those computing devices to be operated at their design specifications without localized cooling starvation in the racks, regardless of the number, type, arrangement, and/or operation of computing devices 120 in other racks 116.

FIG. 6 shows another alternative system 100. In this case, make-up cooling assemblies 122 are positioned in racks 116 of a row 114. In this example, make-up cooling assemblies 122 include auxiliary air conditioning units 124, supply ducts 202, and manifolds 204 positioned within an individual rack 116. The auxiliary air conditioning units 124 are positioned on shelves 200 and computing device 120 are positioned on the remaining shelves. (To avoid clutter on the drawing page, not every instance of manifolds 204, computing device 120, and shelves 200 are labeled on the drawing page).

The make-up cooling assembly 122 on an individual rack 116 can augment cool air flow to locations within the rack to reduce/eliminate localized overheating. For instance, in a retrofit scenario, the rack may have been left empty because of inadequate localized cooling. For example, the opposing rack across the cold air aisle may be loaded with computing devices 120 that have a high thermal load that draws much of the central cooling air 110 from the cold air aisle 112. The present concepts allow the rack 116 to be fitted with make-up cooling assembly 122 and a remainder of the rack to be populated with computing devices 120. The make-up cooling assembly 122 provides localized make-up air cooling to none, some, and/or all of these computing devices 120 depending upon conditions, such as device operating temperature. Thus, the technical solution reduces wasted space and increases computing resource performance per unit area of floorspace within the structure.

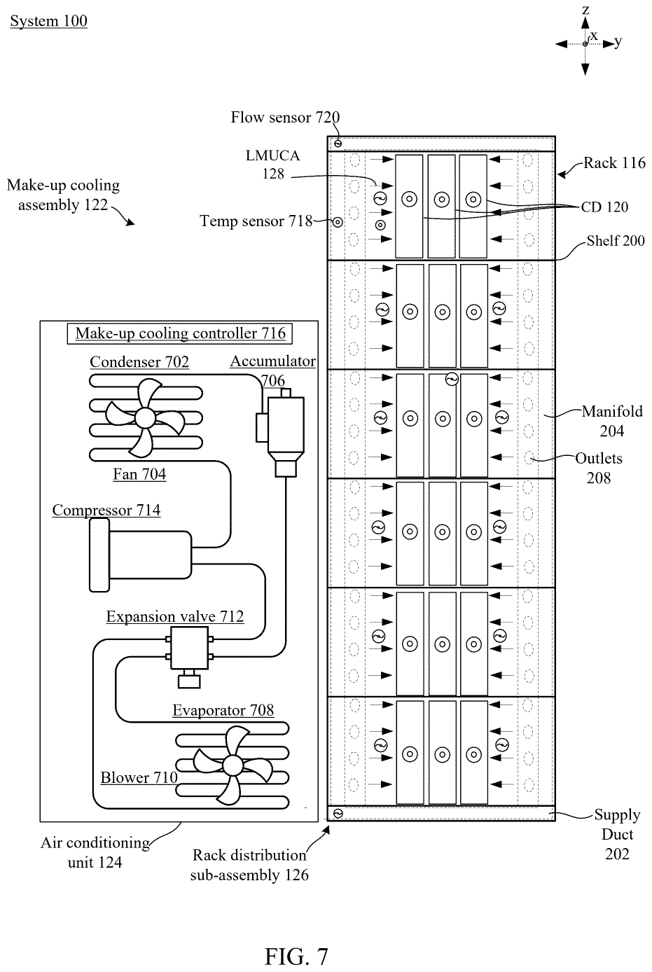

FIG. 7 shows another system 100. In this implementation, the system includes make-up cooling assembly 122 and rack 116. The make-up cooling assembly's auxiliary air conditioning unit 124 includes a condenser 702, a fan 704, an accumulator 706, an evaporator 708, a blower 710, an expansion valve 712, a compressor 714, and a make-up cooling controller 716. The condenser 702, accumulator 706, evaporator 708, expansion valve 712, and compressor 714 are coupled by tubing containing a coolant. The system 100 also includes multiple sensors, such as temperature sensors 718 and/or air flow sensors 720. The sensors 718 and/or 720 can be positioned in the auxiliary air conditioning unit 124 and the rack 116. (Example temperature and airflow sensors are illustrated on the drawing page, but more temperature and airflow sensors and/or other sensors can be employed). Further, to avoid clutter on the drawing page, not all sensors are labelled. Temperature sensors 718 are represented as a circle within a circle. Air flow sensors 720 are represented as a fan blade within a circle.

Temperature sensors 718 can be placed within individual computing devices 120, such as on a housing or directly on a heat generating component of a computing device. For example, processors (e.g., central processing units (CPUs) and/or graphical processing units (GPUs)) are heat-generating components that have recommended and maximum designed operating temperatures. Temperatures sensors 718 on, or proximate to, the processors can provide temperature information to the make-up cooling controller 716 about operating conditions of the processor. (Other locations of the sensors are contemplated beyond those illustrated here).

The auxiliary air conditioning unit 124 receives cool air from the cold air aisle. The evaporator 708 transfers additional heat from this received cool air to the coolant to further cool the cool air. The blower 710 blows the cooler air into the supply ducts 202. The condenser 702 removes heat from the coolant which is transferred to cool air received from the cold air aisle. This now ‘warm air’ is blown by the fan 704 into the hot air return plenum. As mentioned above, the cooler air in the supply ducts 202 travels to the manifolds 204. The manifolds 204 can deliver this cooler air to specific locations within the racks that need additional cooling (e.g., localized make-up cool air).

The make-up cooling controller 716 is electrically coupled to the other components of the auxiliary air conditioning unit 124, such as the compressor 714, fan 704, and/or blower 710. The make-up cooling controller 716 is also electrically coupled to the actuator 306 of the adjustment mechanism 302 (both designated on FIG. 3E). The make-up cooling controller 716 can be physically located in the auxiliary air conditioning unit 124, the racks, or remotely, such as a module on a computing device of the system 100. The make-up cooling controller 716 uses input from the sensors, such as the temperature sensors 718 and/or flow sensors 720, to control the operation of the auxiliary air conditioning unit 124 and/or the manifolds 204 to reduce/eliminate localized undercooling. For instance, temperature and airflow sensors positioned at rack intakes can provide information about the amount and temperature of cooling air entering the rack 116 from the cold air aisle. Similarly, airflow and/or temperature sensors can be positioned within the rack, such as on each shelf 200 and/or on some of all of the computing devices 120 on each shelf.

The make-up cooling controller 716 can receive information about localized cooling airflow for a rack 116 and/or locations (e.g., shelves and/or computing devices) within the rack. As mentioned, the make-up cooling controller 716 can receive local airflow information from the airflow sensors in the locations. In some implementations, the make-up cooling controller 716 can identify a difference (e.g., deficit) between the intended (required to remove the thermal load from the computing device) localized cooling airflow and the delivered (e.g., actual) cooling airflow from the central cooling system. The make-up cooling controller 716 can control the auxiliary air conditioning unit 124 and/or the adjustment mechanisms (302, FIG. 3E) of individual manifolds 204 to correct (e.g., reduce/eliminate) the difference).

The make-up cooling controller 716 can receive or store information about the designed operating temperatures of various heat generating components, such as various processors in the computing devices. The make-up cooling controller 716 can obtain temperature information from temperature sensors 718 positioned on the heat generating components. The make-up cooling controller 716 can control the auxiliary air conditioning unit 124 and/or individual adjustment mechanisms 302 to ensure the actual (e.g., sensed) operating temperature is equal to or below the designed operating temperature (e.g., predefined threshold temperature). For instance, the make-up cooling controller 716 can monitor the operational (e.g., real time) temperatures of the computing devices in racks to which it is coupled.

Based on the monitoring, in the event that individual computing devices 120 exceed their designed operating temperature, the make-up cooling controller 716 can provide more airflow (e.g., localized make-up cooling airflow) from the manifolds 204 on each side of the shelf 200 on which the overheating computing devices 120 are located. For example, if the overheating computing devices are located on the left side of the shelf, the make-up cooling controller 716 could control the corresponding left side manifold to provide more thermal cooling. Thus, the make-up cooling controller 716 provides a technical solution that can provide different make-up cooling to different racks, different shelves within a rack, and/or different locations on a shelf, such as left or right, for example.

Similar to using temperature information to determine how to control the make-up cooling assembly 122, the make-up cooling controller 716 can utilize designed airflow and sensed airflow of computing devices with which it is fluidly associated. The make-up cooling controller 716 can control the make-up cooling assembly 122 to make up for any localized deficiencies, whether they occur at the rack level and/or a more granular level, such as shelf level, locations on a shelf or individual computing devices.

In still other implementations, the make-up cooling controller 716 can utilize sensed local thermal load of individual computing devices or groups of computing devices at a location, such as on a portion of a shelf, a shelf, multiple shelves, or a whole rack. The make-up cooling controller 716 can compare the thermal load to the thermal transfer rate at the location. The thermal transfer rate is related to the flow and temperature of the cooling air passing the local thermal load. If the thermal transfer rate is inadequate to prevent overheating of the local devices (e.g., the thermal load is greater than the thermal transfer rate), the make-up cooling controller 716 can control the make-up cooling assembly 122 to make up for these localized deficiencies by providing localized make-up cooling airflow. For instance, the make-up cooling controller 716 can decrease the temperature of the auxiliary cooler air produced by the auxiliary air conditioning unit 124 and/or increase the velocity (e.g., volume) of auxiliary cooler air supplied to the supply ducts 202. Alternatively or additionally, the make-up cooling controller 716 can control the actuators 306 of the manifolds 204 to increase cooling airflow to the local devices that are overheating to supply a desired (e.g., calculated) amount of localized make-up cooling airflow.

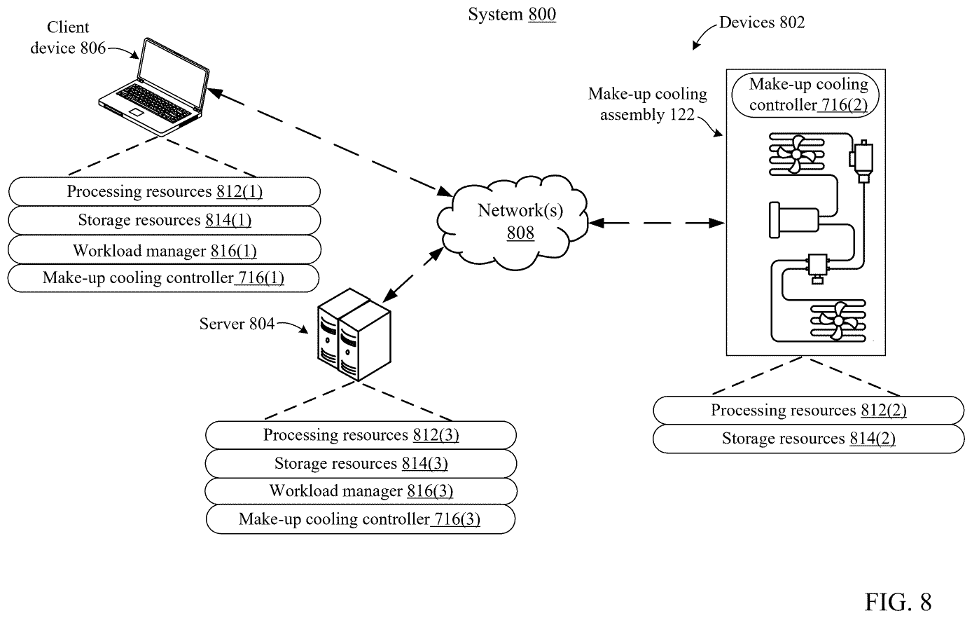

The present implementations can be performed in various scenarios on various devices. FIG. 8 shows details of another example system 800 in which the present implementations can be employed, as discussed in more detail below.

As shown in FIG. 8, system 800 includes devices 802. The devices 802 can include computing devices 120 represented here as servers 804 and can also include switches, routers, etc. The devices 802 can also include client devices 806 and/or make-up cooling assemblies 122. The devices 802 can be coupled by network 808.

Generally, the devices 802 may have respective processing resources 812 and storage resources 814, an instance of make-up cooling controller 716, and/or a workload manager 816. The devices 802 may also have various modules that function using the processing and storage resources to perform the techniques discussed herein. The storage resources 814 can include both persistent storage resources, such as magnetic or solid-state drives, and volatile storage, such as one or more random-access memory devices. In some cases, the modules are provided as executable instructions that are stored on persistent storage devices, loaded into the random-access memory devices, and read from the random-access memory by the processing resources for execution.

As mentioned above, the make-up cooling controller 716 controlling an individual make-up cooling assembly 122 may be physically located on the make-up cooling assembly 122 or remote from the make-up cooling assembly 122. For instance, the make-up cooling controller 716 could occur on the server 804 or the client devices 806. Further, make-up cooling controllers 716 can occur at a one-to-one relationship with the make-up cooling assembly 122. Alternatively, a many-to-one relationship can allow a single make-up cooling controller 716 to control multiple make-up cooling assemblies 122.

Workload manager 816 can have information about the physical location of devices 802 including servers 804 within the structure (102, FIG. 1A), specifications of the devices, and/or workflow of the devices. In some cases, the workload manager may coordinate and/or assign workflow with the servers 804. For instance, the workload manager 816 can include a hypervisor, which can provide virtual machines for running applications. The workload manager 816 can map the workload and hence heat generation (e.g., thermal load) to individual physical devices and their location within the structure (e.g., what rack and what position/location within the rack).

Stated another way, the workload manager 816 has information about the devices 802 including servers 804 within the system, their location, and their components. The workload manager 816 also has information about what applications are operating on individual computing devices, what processes are being performed on the individual computing devices, etc. The workload manager 816 can communicate with the make-up cooling controller 716. In some cases, the make-up cooling controller 716 is a free-standing component. In other cases, the make-up cooling controller 716 can be a sub-component of the workload manager 816.

The make-up cooling controller 716 can use information from the workload manager 816 to proactively manage make-up airflow to individual devices. For instance, servers 804 on a shelf of a rack associated with the make-up cooling controller 716 may be operating at 30 percent processing capacity. Under these operational conditions, the make-up cooling controller 716 may not be providing any local make-up cooling air flow to the computing devices because the system central cooling air may be providing sufficient cooling.

However, if the workflow manager 816 indicates that specific servers 804 are going to be increased to 80 percent capacity, the make-up cooling controller 716 can identify that the central cooling will be insufficient for the heat produced at these operational conditions (e.g., at that thermal load these devices would experience a localized cooling starvation). The make-up cooling controller 716 can proactively signal the actuators (306, FIG. 3E) associated with the manifolds (204, FIG. 3E) that deliver cooling air from the auxiliary air conditioning unit 124 to avoid the cooling air deficiency before it even occurs. This proactive control keeps the computing devices (e.g., the server's processors) operating at desired temperature ranges and avoids a temperature spike that may occur with reactive cooling (e.g., increasing localized cooling air responsive to detecting an increased operational temperature).

In some implementations, the make-up cooling controller 716 can employ or operate cooperatively with machine learning or artificial intelligence. For instance, some implementations can employ machine learning or artificial intelligence to identify which locations (e.g., at the rack level, sub-rack level, shelf level, and/or individual computing device level) should receive make-up cooling and the amount of make-up cooling. For instance, an artificial intelligence (AI) model could be trained relative to system 100 that is managed utilizing both system centralized cooling and make-up cooling to reduce local cooling deficiencies that would otherwise occur. The training data could include the physical location of devices, their workload, their specifications (e.g., number and types of heat generating components and design specifications) and the amount of system cooling air and make-up cooling air provided for a given workload, etc.

Once trained, the AI model could receive workload information and proactively adjust the make-up cooling to specific locations to eliminate overheating without using more make-up cooling than necessary and thereby saving resources. The trained AI model could also determine how and where to apply make-up cooling even in scenarios where the computing devices are upgraded and/or repositioned. For instance, a system (e.g., datacenter) may physically contain 50 percent central processing unit (CPU)-centric computing devices and 50 percent graphical processing unit (GPU)-centric computing devices.

Expected workload shifts may cause some of the CPU-centric computing devices to be replaced with GPU-centric computing devices and/or additional GPU-centric computing devices to be added. For instance, the total number of computing devices could remain constant, but the ratio could be changed to 30 percent CPU-centric computing devices and 70 percent GPU-centric computing devices. The trained AI model, in real-time, can reliably predict individual locations that would benefit from make-up cooling and the amount of make-up cooling to deliver to each location even if that combination of computing device type, number, location, and/or workload had not been previously encountered. The make-up cooling controller 716 can control individual make-up cooling assemblies 122, including at the adjustment mechanism 302 level, to deliver make-up cooling to specific locations to ensure proper thermal management is achieved for these devices according to their thermal load.

Thus, this technical solution ensures computing resources are used efficiently (e.g., approaching, or at, their recommended design specifications) without risking overheating. This efficient use can be accomplished with less electrical consumption because make-up cooling is strategically delivered to individual devices only in the amounts required to maintain their design specifications (e.g., recommended operating temperature) for the workload being performed. Further, the make-up cooling can reduce/eliminate wasted (e.g., unused rack space). For instance, GPU-centric computing devices tend to use more power and hence generate a higher thermal load than CPU-centric computing devices. With existing technology that employs only central system cooling, if a rack is populated with GPU-centric devices, the opposing rack (e.g., across the cold air aisle) is left empty or sparsely populated with computing devices because local cool air starvation occurs. The present make-up cooling air concepts solve this real estate (e.g., rack space) under-utilization by providing make-up cooling air to these locations to rectify localized cooling air starvation.

The term “device” as used herein can mean any type of device that has some amount of hardware processing capability and/or hardware storage/memory capability. Processing capability can be provided by one or more hardware processors (e.g., hardware processing units/cores) that can execute computer-readable instructions to provide functionality. Computer-readable instructions and/or data can be stored on storage, such as storage/memory and/or the datastore. The term “system” as used herein can refer to a single device, multiple devices, etc.

Storage resources can be internal or external to the respective devices with which they are associated. The storage resources can include any one or more of volatile or non-volatile memory, hard drives, flash storage devices, and/or optical storage devices (e.g., compact discs, digital versatile discs, etc.), among others. As used herein, the term “computer-readable media” can include signals. In contrast, the term “computer-readable storage media” excludes signals. Computer-readable storage media includes “computer-readable storage devices.” Examples of computer-readable storage devices include volatile storage media, such as RAM, and non-volatile storage media, such as hard drives, optical discs, and flash memory, among others.

In some cases, the devices are configured with a general-purpose hardware processor and storage resources. In other cases, a device can include a system on a chip (SOC) type design. In SOC design implementations, functionality provided by the device can be integrated on a single SOC or multiple coupled SOCs. One or more associated processors can be configured to coordinate with shared resources, such as memory, storage, etc., and/or one or more dedicated resources, such as hardware blocks configured to perform certain specific functionality. Thus, the term “processor,” “hardware processor” or “hardware processing unit” as used herein can also refer to CPUs, GPUs, controllers, microcontrollers, processor cores, or other types of processing devices suitable for implementation both in conventional computing architectures as well as SOC designs.

Alternatively, or in addition, the functionality described herein can be performed, at least in part, by one or more hardware logic components. For example, and without limitation, illustrative types of hardware logic components that can be used include field-programmable Gate Arrays (FPGAs), application-specific Integrated Circuits (ASICs), application-specific standard products (ASSPs), system-on-a-chip systems (SOCs), complex programmable logic devices (CPLDs), etc.

In some configurations, any of the modules/code discussed herein can be implemented in software, hardware, and/or firmware. In any case, the modules/code can be provided during manufacture of the device or by an intermediary that prepares the device for sale to the end user. In other instances, the end user may install these modules/code later, such as by downloading executable code and installing the executable code on the corresponding device.

Also note that devices may have input and/or output functionality. For example, computing devices can have various input mechanisms such as keyboards, mice, touchpads, voice recognition, gesture recognition (e.g., using depth cameras such as stereoscopic or time-of-flight camera systems, infrared camera systems, red-green-blue camera systems or using accelerometers/gyroscopes, facial recognition, etc.) and/or touch displays. Devices can also have various output mechanisms such as speakers, printers, displays, etc. In further implementations, Internet of Things (IoT) devices can be used in place of or in addition to other types of computing devices discussed herein.

Also note that the devices described herein can function in a stand-alone or cooperative manner to implement the described techniques. For example, the methods and functionality described herein can be performed on a single computing device and/or distributed across multiple computing devices that communicate over network(s) 808. Without limitation, network(s) 808 can include one or more local area networks (LANs), wide area networks (WANs), the Internet, and the like.

### Machine Learning Overview

There are various types of machine learning frameworks that can be trained to perform a given task. Support vector machines, decision trees, and neural networks are just a few examples of machine learning frameworks that have been used in a wide variety of applications, such as image processing and natural language processing. Some machine learning frameworks, such as neural networks, use layers of nodes that perform specific operations.

In a neural network, nodes are connected to one another via one or more edges. A neural network can include an input layer, an output layer, and one or more intermediate layers. Individual nodes can process their respective inputs according to a predefined function, and provide an output to a subsequent layer, or, in some cases, a previous layer. The inputs to a given node can be multiplied by a corresponding weight value for an edge between the input and the node. In addition, nodes can have individual bias values that are also used to produce outputs. Various training procedures can be applied to learn the edge weights and/or bias values. The term “parameters” when used without a modifier is used herein to refer to learnable values such as edge weights and bias values that can be learned by training a machine learning model, such as a neural network.

A neural network structure can have different layers that perform different specific functions. For example, one or more layers of nodes can collectively perform a specific operation, such as pooling, encoding, or convolution operations. For the purposes of this document, the term “layer” refers to a group of nodes that share inputs and outputs, e.g., to or from external sources or other layers in the network. The term “operation” refers to a function that can be performed by one or more layers of nodes. The term “model structure” refers to an overall architecture of a layered model, including the number of layers, the connectivity of the layers, and the type of operations performed by individual layers. The term “neural network structure” refers to the model structure of a neural network. The term “trained model” and/or “tuned model” refers to a model structure together with parameters for the model structure that have been trained or tuned. Note that two trained models can share the same model structure and yet have different values for the parameters, e.g., if the two models are trained on different training data or if there are underlying stochastic processes in the training process.

There are many machine learning tasks for which there is a relative lack of training data. One broad approach to training a model with limited task-specific training data for a particular task involves “transfer learning.” In transfer learning, a model is first pretrained on another task for which significant training data is available, and then the model is tuned to the particular task using the task-specific training data.

The term “pretraining,” as used herein, refers to model training on a set of pretraining data to adjust model parameters in a manner that allows for subsequent tuning of those model parameters to adapt the model for one or more specific tasks. In some cases, the pretraining can involve a self-supervised learning process on unlabeled pretraining data, where a “self-supervised” learning process involves learning from the structure of pretraining examples, potentially in the absence of explicit (e.g., manually-provided) labels. Subsequent modification of model parameters obtained by pretraining is referred to herein as “tuning.” Tuning can be performed for one or more tasks using supervised learning from explicitly-labeled training data, in some cases using a different task for tuning than for pretraining.

### Terminology

For the purposes of this document, the term “language model” refers to any type of automated agent that communicates via natural language. For instance, a language model can be implemented as a neural network, e.g., a decoder-based generative language model such as ChatGPT, a long short-term memory model, etc. The term “generative model,” as used herein, refers to a machine learning model employed to generate new content. Generative models can be trained to predict items in sequences of training data. When employed in inference mode, the output of a generative model can include new sequences of items that the model generates. Thus, a “generative language model” is a model that can generate new sequences of text given some input prompt, e.g., a query potentially with some additional context.

The term “prompt,” as used herein, refers to input text provided to a generative language model that the generative language model uses to generate output text. A prompt can include a query, e.g., a request for information from the generative language model. A prompt can also include context, or additional information that the generative language model uses to respond to the query.

The term “data health issue” refers to any characteristic of a dataset that could impact results of processing that dataset. Examples of data health issues include the presence of corrupted data, erroneous data, improperly formatted data, statistical outliers, etc. The term “data evaluation action” refers to any action performed on a dataset that can identify a data health issue. A “data evaluation plan” is one or more data evaluation actions that can be performed on a given dataset. A “data cleaning action” is an action that attempts to improve data quality by correcting at least one data health issue, e.g., by removing an entry or value from a dataset, changing a value in the dataset to a different value, etc.

A “summary” of a dataset refers to a representation of the dataset as a whole. A summary of a dataset can include data types of fields of the dataset, statistical information for fields of the dataset, and/or annotations of individual fields of the dataset, a set of fields of the dataset, or the dataset as a whole. A “data health score” refers to any metric that characterizes the presence of data health issues in a dataset. A “severity dictionary” is one or more indications of how severe a particular type of data health issue is when present in a dataset. For instance, a severity dictionary can indicate that missing values are relatively more severe than statistical outliers, and can include weights designating the relative severity of each.

The term “machine learning model” refers to any of a broad range of models that can learn to generate automated user input and/or application output by observing properties of past interactions between users and applications. For instance, a machine learning model could be a neural network, a support vector machine, a decision tree, a clustering algorithm, etc. In some cases, a machine learning model can be trained using labeled training data, a reward function, or other mechanisms, and in other cases, a machine learning model can learn by analyzing data without explicit labels or rewards. The term “user-specific model” refers to a model that has at least one component that has been trained or constructed at least partially for a specific user. Thus, this term encompasses models that have been trained entirely for a specific user, models that are initialized using multi-user data and tuned to the specific user, and models that have both generic components trained for multiple users and one or more components trained or tuned for the specific user. Likewise, the term “application-specific model” refers to a model that has at least one component that has been trained or constructed at least partially for a specific application.

The term “pruning” refers to removing parts of a machine learning model while retaining other parts of the machine learning model. For instance, a large machine learning model can be pruned to a smaller machine learning model for a specific task by retaining weights and/or nodes that significantly contribute to the ability of that model to perform a specific task, while removing other weights or nodes that do not significantly contribute to the ability of that model to perform that specific task. A large machine learning model can be distilled into a smaller machine learning model for a specific task by training the smaller machine learning model to approximate the output distribution of the large machine learning model for a task-specific dataset.

### Example Decoder-Based Language Model

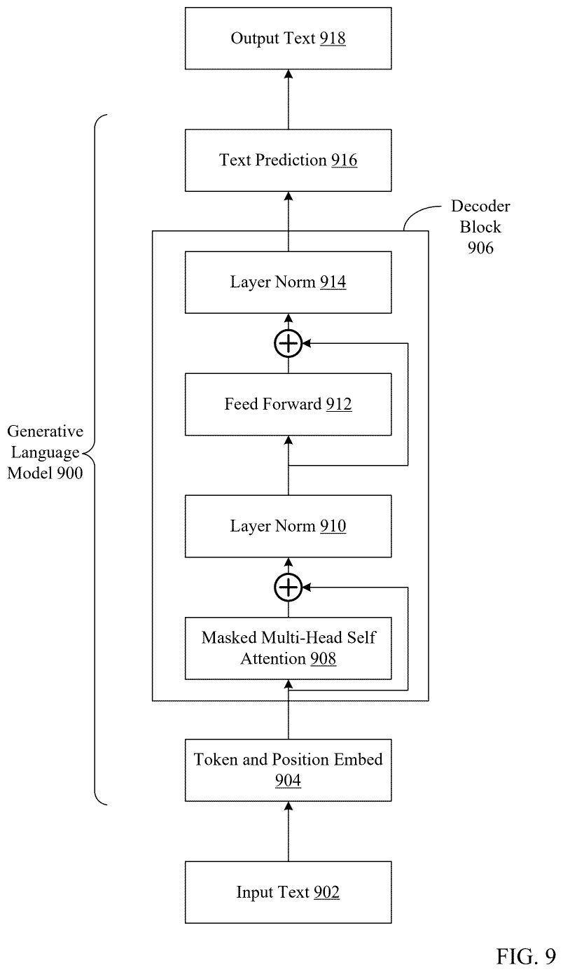

FIG. 9 illustrates an example generative model, such as generative language model 900 that can be employed using the disclosed implementations. Generative language model 900 is an example of a machine learning model that can be used to perform one or more natural language processing tasks that involve generating text, as discussed more below. For the purposes of this document, the term “natural language” means language that is normally used by human beings for writing or conversation.

Generative language model 900 can receive input text 902, e.g., a prompt from a user. For instance, the input text can include words, sentences, phrases, or other representations of language. The input text can be broken into tokens and mapped to token and position embeddings 904 representing the input text. Token embeddings can be represented in a vector space where semantically-similar and/or syntactically-similar embeddings are relatively close to one another, and less semantically-similar or less syntactically-similar tokens are relatively further apart. Position embeddings represent the location of each token in order relative to the other tokens from the input text.

The token and position embeddings 904 are processed in one or more decoder blocks 906. Each decoder block implements masked multi-head self-attention 908, which is a mechanism relating different positions of tokens within the input text to compute the similarities between those tokens. Each token embedding is represented as a weighted sum of other tokens in the input text. Attention is only applied for already-decoded values, and future values are masked. Layer normalization 910 normalizes features to mean values of 0 and variance to 1, resulting in smooth gradients. Feed forward layer 912 transforms these features into a representation suitable for the next iteration of decoding, after which another layer normalization 914 is applied. Multiple instances of decoder blocks can operate sequentially on input text, with each subsequent decoder block operating on the output of a preceding decoder block. After the final decoding block, text prediction layer 916 can predict the next word in the sequence, which is output as output text 918 in response to the input text 902 and also fed back into the language model. The output text can be a newly-generated response to the prompt provided as input text to the generative language model.

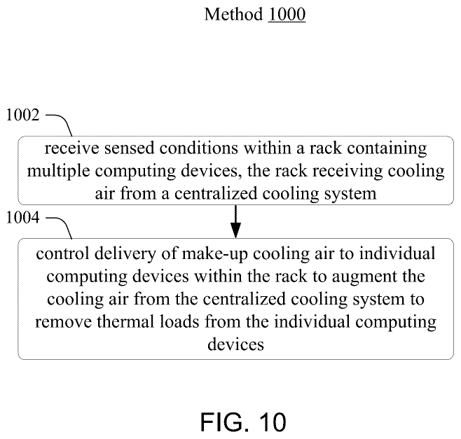

FIG. 10 illustrates an example method 1000, consistent with the present concepts. Method 1000 can be implemented on many different types of devices, e.g., by one or more cloud servers, by a client device such as a laptop, tablet, or smartphone, or by combinations of one or more servers, client devices, etc. For instance, method 1000 can be performed by an instance of make-up cooling controller 716 on servers 804, client device 806, and/or make-up cooling assembly 122.

At block 1002, the method can receive sensed conditions within a rack containing multiple computing devices, the rack receiving cooling air from a centralized cooling system.

At block 1004, the method can control delivery of make-up cooling air to individual computing devices within the rack to augment the cooling air from the centralized cooling system to remove thermal loads from the individual computing devices.

The systems and associated elements described relative to the present concepts can be formed with materials known in the fluid cooling and/or data center technologies. The systems and associated elements can be assembled and/or operated with various methods that are consistent with the present description.

### Additional Examples

Various examples are described above. Additional examples are described below. One example includes a system comprising a structure that separates a controlled environment from an external environment, a centralized cooling system configured to supply relatively cool air inside the structure and to expel heat from relatively hot air from the structure, rows of racks positioned along cold air aisles that are configured to receive the relatively cool air from the centralized cooling system, and a make-up cooling assembly associated with individual racks and configured to deliver additional cool air to a specific location within the individual racks.

Another example can include any of the above and/or below examples where the specific location receives cool air from the cold air aisle that only partially removes a thermal load from a device operating at the specific location.

Another example can include any of the above and/or below examples where the specific location comprises a shelf of the individual rack, a portion of the shelf, or multiple shelves of the rack.

Another example can include any of the above and/or below examples where the make-up cooling assembly is positioned in the individual rack.

Another example can include any of the above and/or below examples where the make-up cooling assembly is positioned in an individual row but not within any of the racks.

Another example can include any of the above and/or below examples where the make-up cooling assembly is configured to selectively deliver additional cool air to multiple specific locations in multiple racks.

Another example can include any of the above and/or below examples where the make-up cooling assembly comprises an auxiliary air conditioning unit to produce the additional cool air and selectively controllable manifolds that are controlled to receive the additional cool air and to deliver the additional cool air to the specific location.

Another example can include any of the above and/or below examples where the selectively controllable manifolds further comprise adjustment mechanisms that are configured to adjust an amount of the additional cool air delivered to the specific location.

Another example can include any of the above and/or below examples where the make-up cooling assembly further comprises a make-up cooling controller that is configured to control the adjustment mechanisms to deliver the amount of additional cool air that in combination with the cool air from the central cooling system removes a thermal load from a device operating at the specific location to maintain an operating temperature within design specifications of the device.

Another example can include any of the above and/or below examples where the make-up cooling controller is further configured to receive air flow and temperature data from the specific location and is further configured to control the adjustment mechanisms so that a thermal transfer rate from the specific location removes a thermal load from the device.

Another example can include any of the above and/or below examples where the make-up cooling controller is configured to utilize design specifications of the device at the specific location and workload information for the device to predict a future thermal load and to control the adjustment mechanisms so that a thermal transfer rate from the specific location removes the predicted future thermal load from the device.

Another example includes a system comprising a rack configured to receive cooling air through a front side and to evacuate warm air through an opposing back side and a make-up cooling assembly positioned proximate to the rack and comprising an auxiliary air conditioning unit configured to generate additional cooling air and a rack distribution sub-assembly configured to selectively deliver the additional cool air to locations within the rack to augment the received cooling air.

Another example can include any of the above and/or below examples where the auxiliary air conditioning unit is positioned in the rack or wherein the auxiliary air conditioning unit is positioned outside of the rack.

Another example can include any of the above and/or below examples where the locations include computing devices and the additional cooling air and the received cooling air collectively remove thermal loads from the computing devices sufficient to keep the computing devices from overheating.

Another example can include any of the above and/or below examples where the rack distribution sub-assembly further includes supply ducts coupling the auxiliary air conditioning unit to manifolds positioned along the rack and wherein the manifolds selectively direct the additional cooling air toward individual computing devices positioned in the rack.

Another example can include any of the above and/or below examples where the manifolds further comprise adjustment mechanisms that control an amount of flow of the additional cooling air toward the individual computing devices.

Another example can include any of the above and/or below examples where the manifolds comprise housings that define outlets and the adjustment mechanisms comprise sliders that define secondary outlets.

Another example can include any of the above and/or below examples where the adjustment mechanisms further comprise electric motors and linkages that couple the electric motors and the sliders, and wherein the electric motors and the linkages are configured to move the sliders to adjust alignment of the secondary outlets relative to the outlets to adjust the flow of the additional cool air on to the individual computing devices.

Another example includes a device-implemented method comprising obtaining sensed conditions within a rack containing multiple computing devices, the rack receiving cooling air from a centralized cooling system and controlling delivery of make-up cooling air to individual computing devices within the rack to augment the cooling air from the centralized cooling system to remove thermal loads from the individual computing devices.

Another example can include any of the above and/or below examples where controlling delivery comprises controlling delivery to individual computing devices, portions of shelves of the rack on which the individual computing devices are positioned, or entire shelves of the rack on which the individual computing devices are positioned.

### Conclusion

Although the subject matter relating to make-up cooling has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A system, comprising:
a structure that separates a controlled environment from an external environment;
a centralized cooling system configured to supply relatively cool air inside the structure and to expel heat from relatively hot air from the structure;
rows of racks positioned along cold air aisles that are configured to receive the relatively cool air from the centralized cooling system; and,
a make-up cooling assembly associated with individual racks and configured to deliver additional cool air to a specific location within the individual racks.

2. The system of claim 1, wherein the specific location receives cool air from the cold air aisle that only partially removes a thermal load from a device operating at the specific location.

3. The system of claim 2, wherein the specific location comprises a shelf of the individual rack, a portion of the shelf, or multiple shelves of the rack.

4. The system of claim 3, wherein the make-up cooling assembly is positioned in the individual rack.

5. The system of claim 1, wherein the make-up cooling assembly is positioned in an individual row but not within any of the racks.

6. The system of claim 1, wherein the make-up cooling assembly is configured to selectively deliver additional cool air to multiple specific locations in multiple racks.

7. The system of claim 1, wherein the make-up cooling assembly comprises an auxiliary air conditioning unit to produce the additional cool air and selectively controllable manifolds that are controlled to receive the additional cool air and to deliver the additional cool air to the specific location.

8. The system of claim 7, wherein the selectively controllable manifolds further comprise adjustment mechanisms that are configured to adjust an amount of the additional cool air delivered to the specific location.

9. The system of claim 8, wherein the make-up cooling assembly further comprises a make-up cooling controller that is configured to control the adjustment mechanisms to deliver the amount of the additional cooling air that in combination with the cool air from the central cooling system removes a thermal load from a device operating at the specific location to maintain an operating temperature within design specifications of the device.

10. The system of claim 9, wherein the make-up cooling controller is further configured to receive air flow and temperature data from the specific location and is further configured to control the adjustment mechanisms so that a thermal transfer rate from the specific location removes the thermal load from the device.

11. The system of claim 9, wherein the make-up cooling controller is configured to utilize the design specifications of the device at the specific location and workload information for the device to predict a future thermal load and to control the adjustment mechanisms so that a thermal transfer rate from the specific location removes the predicted future thermal load from the device.

12. A system, comprising:
a rack configured to receive cooling air through a front side and to evacuate warm air through an opposing back side; and,
a make-up cooling assembly positioned proximate to the rack and comprising an auxiliary air conditioning unit configured to generate additional cooling air and a rack distribution sub-assembly configured to selectively deliver the additional cooling air to locations within the rack to augment the received cooling air.

13. The system of claim 12, wherein the auxiliary air conditioning unit is positioned in the rack or wherein the auxiliary air conditioning unit is positioned outside of the rack.

14. The system of claim 12, wherein the locations include computing devices and the additional cooling air and the received cooling air collectively remove thermal loads from the computing devices sufficient to keep the computing devices from overheating.

15. The system of claim 12, wherein the rack distribution sub-assembly further includes supply ducts coupling the auxiliary air conditioning unit to manifolds positioned along the rack and wherein the manifolds selectively direct the additional cooling air toward individual computing devices positioned in the rack.

16. The system of claim 15, wherein the manifolds further comprise adjustment mechanisms that control an amount of flow of the additional cooling air toward the individual computing devices.

17. The system of claim 16, wherein the manifolds comprise housings that define outlets and the adjustment mechanisms comprise sliders that define secondary outlets.

18. The system of claim 17, wherein the adjustment mechanisms further comprise electric motors and linkages that couple the electric motors and the sliders, and wherein the electric motors and the linkages are configured to move the sliders to adjust alignment of the secondary outlets relative to the outlets to adjust the flow of the additional cooling air on to the individual computing devices.

19. A device-implemented method, comprising:
obtaining sensed conditions within a rack containing multiple computing devices, the rack receiving cooling air from a centralized cooling system; and,
controlling delivery of make-up cooling air to individual computing devices within the rack to augment the cooling air from the centralized cooling system to remove thermal loads from the individual computing devices.

20. The method of claim 19, wherein controlling delivery comprises controlling delivery to individual computing devices, portions of shelves of the rack on which the individual computing devices are positioned, or entire shelves of the rack on which the individual computing devices are positioned.
